(19) United States
(12) Patent Application Publication
(10) Pub. No.: US 2008/0067566 A1
(43) Pub. Date: Mar. 20, 2008

(54) Contact structure having conductive oxide layer, ferroelectric random access memory device employing the same and methods of fabricating the same

(76) Inventors: Do-Yeon Choi, Seoul (KR); Hee-San Kim, Seoul (KR); Heung-Jin Joo, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/797,138

(22) Filed: May 1, 2007

(30) Foreign Application Priority Data
Sep. 15, 2006 (KR) 10-2006-0089496

(51) Int. Cl. H01L 23/48; H01L 21/00; H01L 29/94

(52) U.S. Cl. 257/295; 257/763; 438/3; 257/E21.009; 257/E21.664

(57) ABSTRACT

A ferroelectric memory device may include a substrate, an interlayer insulating layer on the semiconductor substrate, a contact plug penetrating the interlayer insulating layer, the contact plug being formed of a sequentially stacked metal plug and buffer plug, a conductive protection pattern covering the contact plug, the conductive protection pattern being a conductive oxide layer, a lower electrode, a ferroelectric pattern, and an upper electrode sequentially stacked on the conductive protection pattern, and an insulating protection layer covering the sequentially stacked lower electrode, ferroelectric pattern, and upper electrode.

### BACKGROUND OF THE INVENTION

1. Field of the Invention

The present invention relates to a semiconductor device and a method of fabricating the same and, more particularly, to a contact structure having a conductive oxide layer, a ferroelectric memory device employing the same and methods of fabricating the same.

2. Description of the Related Art

A ferroelectric memory device may include multiple ferroelectric memory cells, and each of the ferroelectric memory cells may have a ferroelectric capacitor composed of a sequentially stacked lower electrode, ferroelectric layer and upper electrode. The ferroelectric capacitor may be covered by an interlayer insulating layer, e.g., a silicon oxide layer. Accordingly, when a subsequent process, e.g., a plasma process, is carried out, hydrogen ions may penetrate into the ferroelectric layer through the interlayer insulating layer. When the hydrogen ions penetrate into the ferroelectric layer, the characteristics of the ferroelectric layer, i.e., the polarization characteristics, may deteriorate. This phenomenon arises because the hydrogen ions may react with oxygen ions within the ferroelectric layer to cause oxygen vacancies. As a result, there is a need for new technologies to produce ferroelectric memory devices having superior characteristics.

### SUMMARY OF THE INVENTION

The present invention is therefore directed to a ferroelectric memory device that overcomes one or more of the limitations and disadvantages of the related art.

It is therefore a feature of an embodiment of the present invention to provide a ferroelectric memory device having a thermally stable contact structure.

It is therefore a feature of an embodiment of the present invention to provide a ferroelectric memory device having a hydrogen barrier layer entirely covering a ferroelectric capacitor and employing a thermally stable contact structure.

At least one of the above and other features and advantages of the present invention may be realized by providing a contact structure that may include a semiconductor substrate, an interlayer insulating layer that may be on the semiconductor substrate, a contact plug that may penetrate the interlayer insulating layer, where the contact plug may be a sequentially stacked metal plug and buffer plug, a conductive protection pattern that may cover the contact plug, where the conductive protection pattern may be a conductive oxide layer, a lower electrode, a ferroelectric pattern, and an upper electrode sequentially stacked on the conductive protection pattern, and an insulating protection layer that may cover the sequentially stacked lower electrode, ferroelectric pattern, and upper electrode.

The metal plug may be composed of tungsten. The buffer plug may be composed of at least one of metal nitride or conductive oxide. The buffer plug and the conductive protection pattern may be formed of the same material formed by one process. The conductive protection pattern may include at least one of a SrRuO₃ layer, a Y₂(Ba,Cu)O₅ layer, a (La,Sr)CoO₃ layer, a LaNiO₃ layer or a RuO₂ layer.

At least one of the above and other features and advantages of the present invention may be realized by providing a ferroelectric memory device that may include a semiconductor substrate, an interlayer insulating film that may be on the semiconductor substrate, a contact plug that may penetrate the interlayer insulating layer, where the contact plug may be composed of a sequentially stacked metal plug and buffer plug, a conductive protection pattern that may cover the contact plug, where the conductive protection pattern may be a conductive oxide layer, a lower electrode, a ferroelectric pattern, and an upper electrode sequentially stacked on the conductive protection pattern, and an insulating protection layer that may cover the sequentially stacked lower electrode, ferroelectric pattern, and upper electrode.

The metal plug may be composed of tungsten. The buffer plug may be a metal nitride plug or a conductive oxide plug. The metal nitride plug may be composed of at least one of TiN or TiAlN, and the conductive oxide plug may be composed of at least one of SrRuO₃, Y₂(Ba,Cu)O₅, (La,Sr)CoO₃, LaNiO₃, or RuO₂. The conductive oxide layer may include at least one of a SrRuO₃ layer, a Y₂(Ba,Cu)O₅ layer, a (La,Sr)CoO₃ layer, a LaNiO₃ layer or a RuO₂ layer. The lower electrode may be formed of a sequentially stacked first conductive pattern and second conductive pattern, the first conductive pattern may be composed of at least one of a TiN layer, a TiSiN layer, a TaN layer, a TiAlN layer, or a TaAlN layer, and the second conductive pattern may be composed from at least one of a Pt layer, a Ru layer, an Ir layer, or an IrO₂ layer. The conductive protection pattern may be formed of the same material during one process. The insulating protection layer may be composed of at least one of an Al₂O₃ layer, a SiON layer, or a SiN layer.

At least one of the above and other features and advantages of the present invention may be realized by providing a method of fabricating a ferroelectric memory device which may include forming an interlayer insulating layer having a contact hole on a semiconductor substrate, forming a contact plug composed of a metal plug and a buffer plug which may sequentially fill the contact hole, forming a conductive protection layer that may be composed of a conductive oxide layer on the substrate having the contact plug, forming a sequentially stacked lower conductive layer, ferroelectric layer, and upper conductive layer that may be on the conductive protection layer, sequentially patterning the upper conductive layer, the ferroelectric layer, the lower conductive layer, and the conductive protection layer to form a conductive protection pattern, a lower electrode, a ferroelectric pattern, and an upper electrode which may be sequentially stacked on the contact plug, and forming an insulating protection layer that may be on the substrate having the conductive protection pattern, the lower electrode, the ferroelectric pattern, and the upper electrode.

The buffer plug may be formed of a metal nitride layer or a conductive oxide layer. The conductive oxide layer may include at least one of a SrRuO₃ layer, a Y₂(Ba,Cu)O₅ layer, a (La,Sr)CoO₃ layer, a LaNiO₃ layer or a RuO₂ layer. Forming the contact plug may include forming a metal layer on the interlayer insulating layer having the contact hole, planarizing the metal layer until the interlayer insulating layer is exposed, etching-back the planarized metal layer to form a metal plug partially filling the contact hole, forming a buffer conductive layer on the substrate having the metal plug, and planarizing the buffer conductive layer to form a buffer plug filling the rest portion of the contact hole. The buffer plug may be formed while the conductive protection layer is formed. Forming the contact plug and the conductive protection layer may include forming a metal plug partially filling the contact hole, forming a conductive oxide layer which may fill a rest portion of the contact hole and covers the interlayer insulating layer, and partially planarizing the conductive oxide layer so as to make a portion of the conductive oxide layer remain on the interlayer insulating layer using a partial CMP process. The lower conductive layer may be composed of a first conductive layer and a second conductive layer which are sequentially stacked, the first conductive layer may include at least one of a TiN layer, a TiSiN layer, a TaN layer, a TiAlN layer or a TaAlN layer, and the second conductive layer may include at least one of a Pt layer, a Ru layer, an Ir layer or an IrO₂ layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1A and 1B illustrate cross-sectional views of stages of a method of fabricating a ferroelectric memory device.

FIGS. 2A and 2B illustrate cross-sectional views of stages of a method of fabricating another ferroelectric memory device.

FIGS. 3A to 3D illustrate cross-sectional views of stages of a method of fabricating a ferroelectric memory device in accordance with an exemplary embodiment of the present invention.

FIGS. 4A to 4C illustrate cross-sectional views of stages of a method of fabricating a ferroelectric memory device in accordance with another exemplary embodiment of the present invention.

### DETAILED DESCRIPTION OF THE INVENTION

Korean Patent Application No. 10-2006-0089496, filed on Sep. 15, 2006, in the Korean Intellectual Property Office, and entitled: “Contact Structure Having Conductive Oxide Layer, Ferroelectric Random Access Memory Device Employing the Same and Methods of Fabricating the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

To prevent the hydrogen ions from penetrating into a ferroelectric capacitor, a technique of forming a hydrogen barrier layer covering the top surface of the ferroelectric capacitor may be widely employed. A ferroelectric capacitor may be formed on a semiconductor substrate, and an insulating layer and a hydrogen barrier layer covering the ferroelectric capacitor may be formed. As such, even when the hydrogen barrier layer covering the ferroelectric capacitor is formed, it may be difficult to prevent hydrogen ions generated by subsequent processes, e.g., a tungsten plug formation process in a peripheral region, from diffusing into the ferroelectric layer from the bottom of the ferroelectric capacitor.

Ferroelectric materials, e.g., PZT (Pb(Zr,Ti)O₃), SBT (SrBi₂Ta₂O₉), etc., may be frequently used as the ferroelectric layer of a ferroelectric capacitor. These ferroelectric materials may have a dielectric constant of about several hundred to about several thousand at room temperature, and have two stable remnant polarizations. These ferroelectric materials may accordingly become too thin to be used for a ferroelectric memory device. A ferroelectric memory device using a ferroelectric thin film may utilize hysteresis characteristics, which adjust a polarization direction toward the direction of an applied electric field to input a signal and store digital signals “1” and “0” by the direction of the remnant polarization when the electric field is removed.

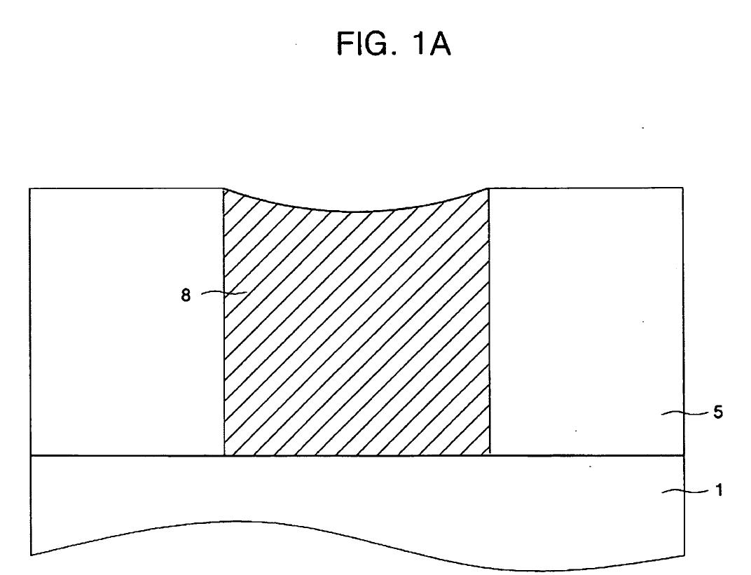

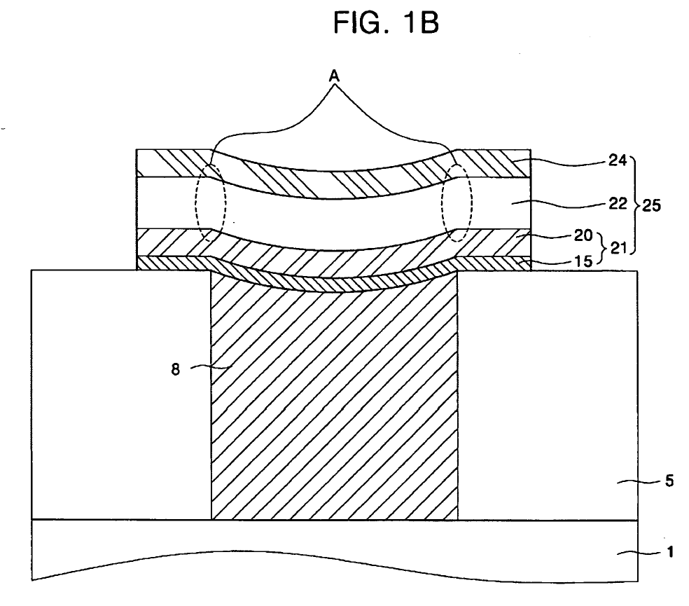

FIGS. 1A and 1B illustrate cross-sectional views of stages of a method of fabricating a ferroelectric memory device.

Referring to FIG. 1A, a lower structure (not shown) including a gate electrode, and source and drain regions may be formed in a semiconductor substrate 1, and then an interlayer insulating layer 5 may be formed on the entire surface of the semiconductor substrate 1. In general, the interlayer insulating layer 5 may be formed of, e.g., silicon oxide, etc. The interlayer insulating layer 5 may then be selectively etched to form a contact hole exposing a predetermined region of the semiconductor substrate 1. A metal layer may be formed on the semiconductor substrate having the contact hole. The metal layer may be formed of, e.g., tungsten, etc. The metal layer may be planarized by, e.g., a chemical mechanical polishing (CMP) process, until the interlayer insulating layer 5 is exposed. As a result, a contact plug 8 filling the contact hole may be formed. In general, the metal layer, e.g., a tungsten layer, may have a hardness lower than that of the interlayer insulating layer 5. The interlayer insulating layer 5 may thus be harder than the metal layer. Accordingly, when a CMP process is performed to planarize the metal layer until the top surface of the interlayer insulating layer 5 is exposed, an upper region of the contact plug 8 may be etched faster to cause a dishing region.

Referring to FIG. 1B, a lower conductive layer, a ferroelectric layer, and an upper conductive layer may be sequentially formed on the semiconductor substrate having the contact plug 8. In this case, the upper region of the dishing region may be formed along the uneven surface of the dishing region so that these layers have concave regions. The upper conductive layer, the ferroelectric layer, and the lower conductive layer may be sequentially patterned to form a lower electrode 21, a ferroelectric pattern 22, and an upper electrode 24 which may be sequentially stacked on the contact plug 8. The lower electrode 21, the ferroelectric pattern 22, and the upper electrode 24 may constitute a ferroelectric capacitor 25. In this case, the lower electrode 21 may be composed of a sequentially stacked first conductive pattern 15 and a second conductive pattern 20. The first conductive pattern 15 may act as a barrier which prevents the second conductive pattern 20 from being oxidized or prevents elements constituting the second conductive pattern 20 from diffusing downward. The first conductive pattern 15 may be formed of, e.g., a TiAlN layer, etc.

The ferroelectric capacitor may 25 include concave regions in the upper region of the dishing region. In particular, the ferroelectric pattern 22 may be formed along the uneven surface of the lower electrode 20 to have parts A grown in a sloped direction. Accordingly, the polarization direction of the parts A grown in the sloped direction, when the polarization occurs in the direction of the applied electric field, may not be the same as other regions. As a result, the hysteresis characteristic may deteriorate due to the parts A grown in the sloped direction. When the hysteresis characteristic severely deteriorates, the characteristic of the ferroelectric capacitor may deteriorate.

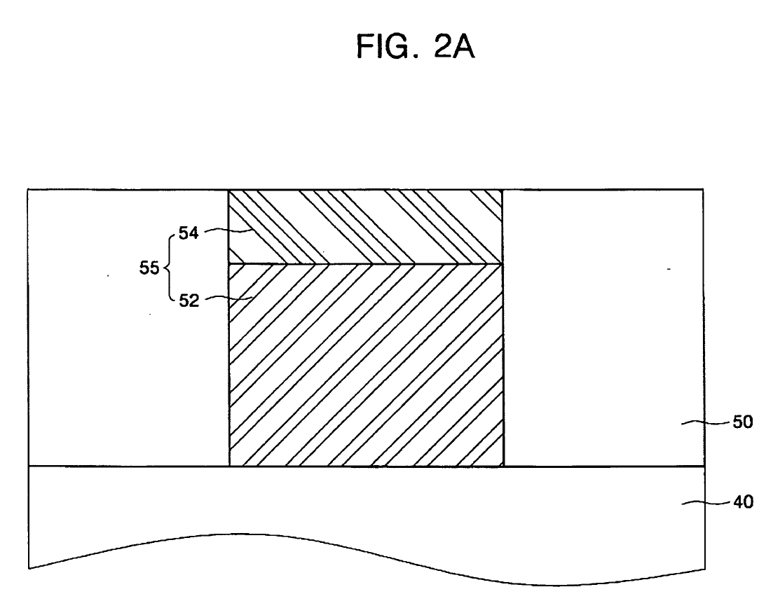

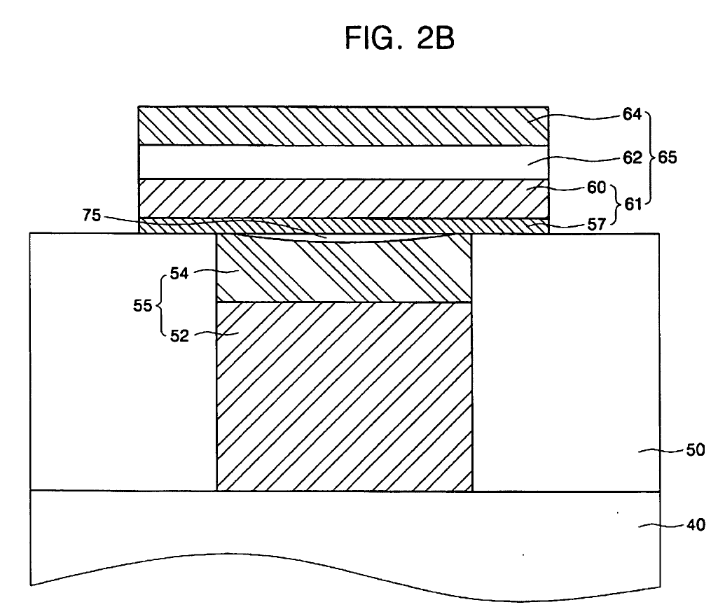

FIGS. 2A and 2B illustrate cross-sectional views of stages of a method of fabricating another ferroelectric memory device.

Referring to FIG. 2A, an interlayer insulating layer 50 may be formed on a semiconductor substrate 40. The interlayer insulating layer 50 may then be selectively etched to form a contact hole exposing a predetermined region of the semiconductor substrate 40. A contact plug 55 composed of, e.g., a tungsten plug 52 and a titanium nitride (TiN) plug 54, which sequentially fill the contact hole may be formed. The contact plug 55 may be composed of the tungsten plug 52 and the titanium nitride plug 54 because the tungsten plug 52 may act to prevent a dishing region from occurring. In detail, after a tungsten layer is formed on a substrate having a contact hole and then planarized, the planarized tungsten layer may be etched back to form the tungsten plug 52 being recessed from the top surface of the interlayer insulating layer 50. The tungsten plug 52 may thus partially fill the contact hole.

Subsequently, a chemical vapor deposition (CVD) TiN layer or an atomic layer deposition (ALD) TiN layer, which may have a good burial characteristic and have no seam, may be formed on the semiconductor substrate having the tungsten plug 52. The TiN layer may be planarized to form the TiN plug 54 on the tungsten plug 52. Accordingly, a contact plug 55 sequentially composed of the tungsten plug 52 and the TiN plug 54 may fill the contact hole.

Referring to FIG. 2B, a lower electrode 61, a ferroelectric pattern 62, and an upper electrode 64 may be sequentially stacked above the contact plug 55. The lower electrode 61, the ferroelectric pattern 62, and the upper electrode 64 may constitute a ferroelectric capacitor 65. In this case, the lower electrode 61 may be formed of a sequentially stacked first conductive pattern 57 and a second conductive pattern 60. The first conductive pattern 57 may act as a barrier which prevents the second conductive pattern 60 from being oxidized or prevents elements constituting the second conductive pattern 60 from diffusing downward. The first conductive pattern 57 may be formed of, e.g., a TiAlN layer.

The ferroelectric pattern 65 may be formed without an uneven surface. However, high temperature processes, among processes after the formation of the lower electrode 61, may be performed on the pattern. A fine gap 75 may occur between the TiN plug 54 and the lower electrode 61 due to the change in heat generated during the subsequent processes. The TiN plug 54 may recrystallize and thus shrink due to the changes in heat generated from the subsequent high temperature processes at. As a result, a fine gap 75 may occur between the TiN plug 54 and the first conductive pattern 57. The fine gap 75 may occur between a contact plug formed of a metal material and a metal pattern having a plate shape covering the contact plug. In addition, as semiconductor devices become more highly integrated, the effect of the fine gap 75 on the electrical characteristics of the semiconductor device may further increase. That is, the fine gap 75 may deteriorate the ohmic contact characteristics between the TiN plug 54 and the first conductive pattern 57. Accordingly, the electrical characteristics of the ferroelectric memory device may deteriorate.

According to the present invention, a conductive protection pattern formed of a conductive oxide layer, which is thermally stable and is capable of preventing hydrogen diffusion, may be provided between a lower electrode and a contact plug. The conductive protection pattern may be interposed between the contact plug formed of a metal material and the lower electrode covering the contact plug. Since a thermally stable conductive protection pattern may be provided, a fine gap between the contact plug and the lower electrode may be prevented from occurring due to changes in heat generated while subsequent processes are carried out. The conductive protection pattern may cover the bottom of a ferroelectric capacitor. Further, an insulating protection layer may be provided to cover the top and sides of the ferroelectric capacitor. The conductive protection pattern and the insulating protection layer may entirely cover the ferroelectric capacitor, so that they can prevent external hydrogen ions from diffusing into the ferroelectric capacitor. Consequently, not only polarization characteristics of the ferroelectric capacitors, but also electrical characteristics of a ferroelectric memory device, may be prevented from deteriorating.

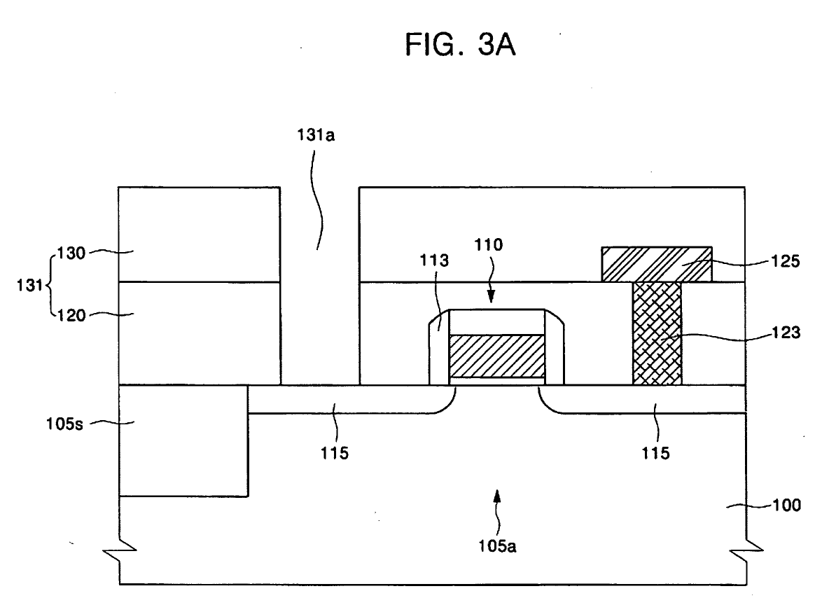

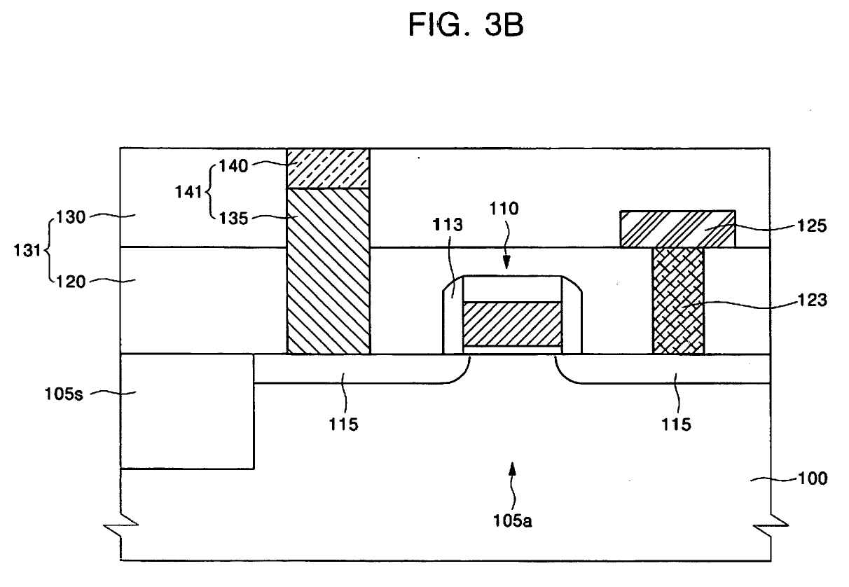

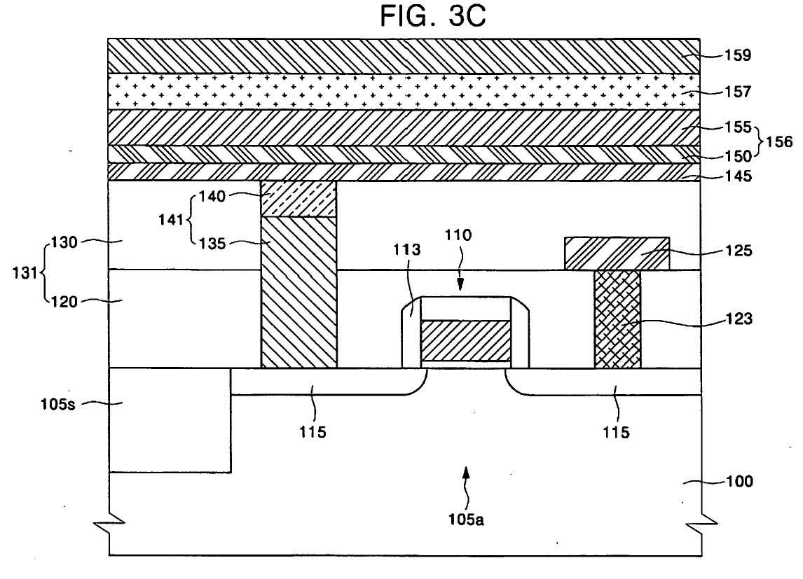

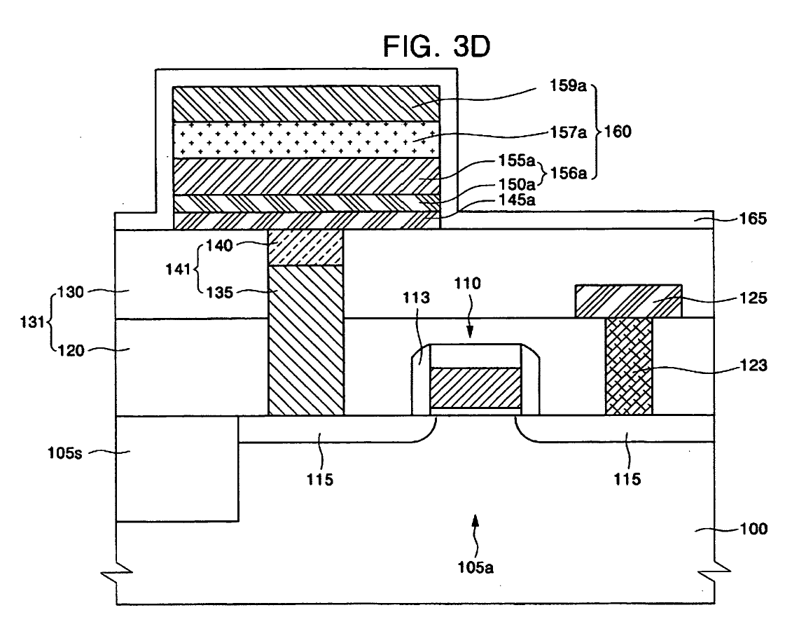

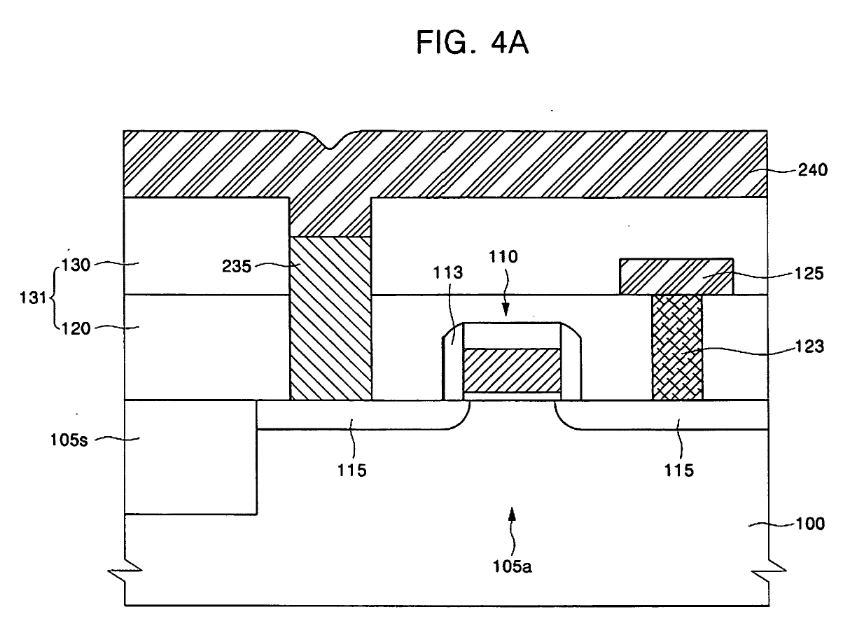

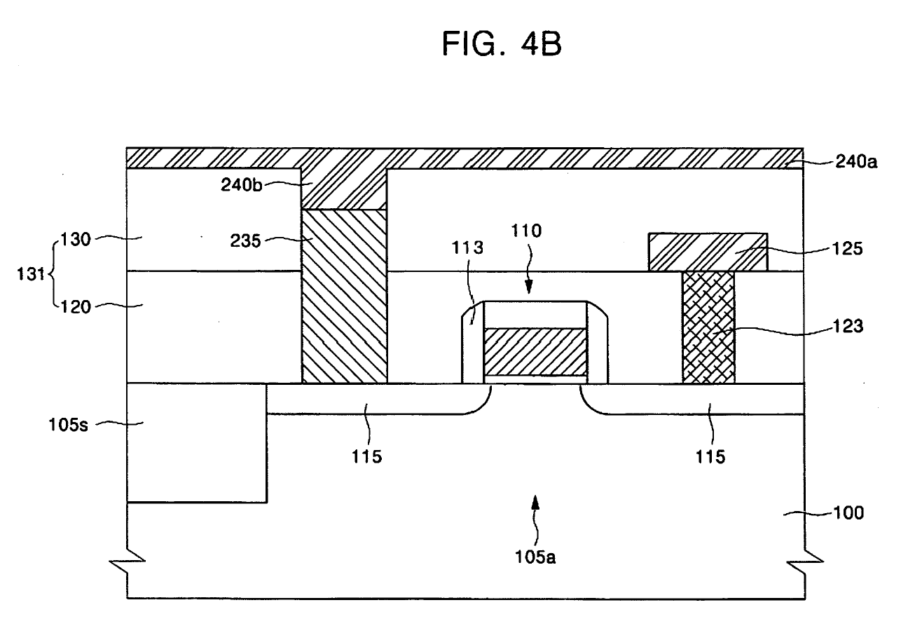

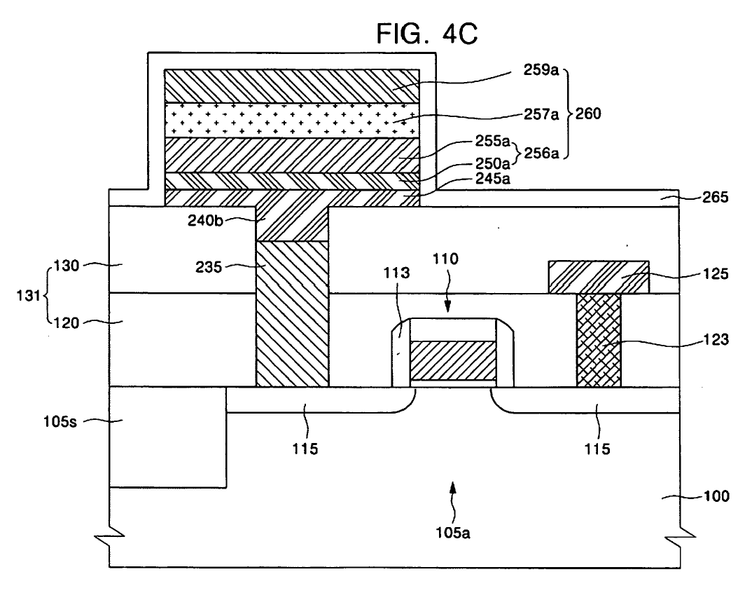

FIGS. 3A to 3D illustrate cross-sectional views of stages of a method of fabricating a ferroelectric memory device in accordance with an exemplary embodiment of the present invention, and FIGS. 4A to 4C illustrate cross-sectional views of stages of a method of fabricating a ferroelectric memory device in accordance with another exemplary embodiment of the present invention.

A ferroelectric memory device according to exemplary embodiments of the present invention will be first described with reference to FIG. 3D.

Referring to FIG. 3D, an isolation layer 105s defining an active region 105a may be formed in a semiconductor substrate 100. A switching device may be formed in the active region 105a. The switching device may be a metal oxide semiconductor (MOS) transistor composed of a gate pattern 110 disposed on the active region 105a and impurity regions 115 disposed in the active region at both sides of the gate pattern 110. The gate pattern 110 may include a sequentially stacked gate insulating layer and a gate electrode. Further, the gate pattern 110 may include a capping layer disposed on the gate electrode. The impurity regions 115 may be defined as source and drain regions. A gate spacer 113 may be disposed on at least one sidewall of the gate pattern 110.

A lower interlayer insulating layer 120 may be on the substrate having the switching device. A direct contact plug 123 may penetrate through the lower interlayer insulating layer 120 to electrically connect to one region of the impurity regions 115. A conductive line 125 may be on the lower interlayer insulating layer 120 to cover the direct contact plug 123.

An upper interlayer insulating layer 130 may be on the substrate having the conductive line 125. The upper interlayer insulating layer 130 and the lower interlayer insulating layer 120 may constitute an interlayer insulating layer 131. A contact plug 141 may penetrate the interlayer insulating layer 131. The contact plug 141 may electrically connect to one region of the impurity regions 115. The direct contact plug 123 may electrically connect to one region of the impurity regions 115, and the contact plug 141 may electrically connect to the other region of the impurity regions 115.

The contact plug 141 may be composed of a sequentially stacked metal plug 135 and buffer plug 140. The metal plug 135 may be composed of a material which has good electrical conductivity and a good burial characteristic. The metal plug 135 may be, e.g., a tungsten plug.

The buffer plug 140 may be composed of a material having a hardness higher than that of the metal plug 135. The buffer plug 140 may be, e.g., a metal nitride plug, a conductive oxide plug, etc. The metal nitride plug may be, e.g., a TiN plug, a TiAlN plug, etc. The conductive oxide plug may be, e.g., a SrRuO₃ plug, a Y₂(Ba,Cu)O₅ plug, a (La,Sr)CoO₃ plug, a LaNiO₃ plug, a RuO₂ plug, etc.

A conductive protection pattern 145a covering the contact plug 141 may be on the interlayer insulating layer 131. The conductive protection pattern 145a may be composed of a conductive oxide layer which is thermally stable and is capable of preventing hydrogen diffusion. The conductive protection pattern 145a may be formed of a conductive oxide layer including at least one of, e.g., a SrRuO₃ layer, a Y₂(Ba,Cu)O₅ layer, a (La,Sr)CoO₃ layer, a LaNiO₃ layer, a RuO₂ layer, etc.

A ferroelectric capacitor 160 composed of a sequentially stacked lower electrode 156a, a ferroelectric pattern 157a, and an upper electrode 159a, may be on the conductive protection pattern 145a. The lower electrode 156a may be composed of a sequentially stacked first conductive pattern 150a and a second conductive pattern 155a. The first conductive pattern 150a may include at least one of, e.g., a TiN layer, a TiSiN layer, a TaN layer, a TiAlN layer, a TaAlN layer, etc. The second conductive pattern 155a may include at least one of, e.g., a Pt layer, a Ru layer, an Ir layer, an IrO₂ layer, etc. The first conductive pattern 150a may act as a barrier which may prevent the second conductive pattern 155a from being oxidized, may prevent elements constituting the second conductive pattern 155a from diffusing downward, and may prevent elements constituting the layers below the first conductive pattern from diffusing into the second conductive pattern 155a. The ferroelectric pattern 157a may include at least one of, e.g., PZT (Pb(Zr,Ti)O₃), SBT (SrBi₂Ta₂O₉), SBTN (SrₓBi_{y}(TaᵢNbⱼ)₂O₉), BLT ((Bi₄₋ₓ,Laₓ)Ti₃O₁₂), etc. The upper electrode 159a may include at least one of, e.g., Pt, Ru, Ir, IrO₂, SrRuO₃, etc.

The conductive protection pattern 145a may enhance an adhesive characteristic between the contact plug 141 and the lower electrode 156a. The conductive protection pattern 145a may be formed of a conductive oxide layer which is thermally stable and has a good adhesive strength with the contact plug 141 and the lower electrode 156a. A bonding strength between the conductive protection pattern 145a and the contact plug 141 may be higher than that between a general contact plug and a metal pattern in contact with the general contact plug. Accordingly, the conductive protection pattern 145a may be disposed between the contact plug 141 and the lower electrode 156a so that a fine gap between the contact plug 141 and the lower electrode 156a may be prevented from occurring.

The buffer plug 140 and the conductive protection pattern 145a may be formed of the same material by one process. The buffer plug 140 and the conductive protection pattern 145a may be formed of the same material including at least one of, e.g., a SrRuO₃ layer, a Y₂(Ba,Cu)O₅ layer, a (La,Sr)CoO₃ layer, a LaNiO₃ layer, a RuO₂ layer, etc.

According to the present invention, a micro-lifting phenomenon occurring between heterogeneous metal patterns, due to stress caused by a change in heat during subsequent processes at high temperature, may be prevented. A conductive oxide layer may be interposed between metal patterns formed by different processes, so that a fine gap between metal patterns due to a change in heat during subsequent processes may be prevented from occurring. The contact plug 141 and the lower electrode 156a may be formed by different processes in the present invention, and the conductive protection pattern 145a may be interposed between the contact plug 141 and the lower electrode 156a so that any micro-lifting phenomena may be prevented.

A contact structure of the this embodiment of the present invention may include the contact plug 141, composed of the sequentially stacked metal plug 135 and the buffer plug 140, the lower electrode 156a covering the contact plug 141, and the conductive protection pattern 145a interposed between the contact plug 141 and the lower electrode 156a. The contact structure may have other forms. For example, the contact structure may be used for various semiconductor devices provided with other metal patterns instead of the lower electrode 156a of the present invention. A contact structure may be provided to include the contact plug 141 and the conductive protection pattern 145a being in common, and the contact structure may include metal patterns formed of the same material as the lower electrode 156a or different materials, e.g., tungsten, copper, etc., than the lower electrode 156a.

An insulating protection layer 165 may be on the substrate having the ferroelectric capacitor 160. The insulating protection layer 165 may cover the ferroelectric capacitor 160. The insulating protection layer 165 may include at least one of, e.g., an Al₂O₃ layer, a SiON layer, a SiN layer, etc. The insulating protection layer 165 and the conductive protection pattern 145a may prevent external hydrogen from diffusing into the ferroelectric capacitor 160. The insulating protection layer 165 and the conductive protection pattern 145a may entirely cover the ferroelectric capacitor 160, so that external hydrogen may be prevented from diffusing into the ferroelectric capacitor 160.

Hereinafter, methods of fabricating a ferroelectric memory device according to exemplary embodiments of the present invention will be described.

A method of fabricating a ferroelectric memory device according to an exemplary embodiment of the present invention will be first described with reference to FIGS. 3A to 3D.

Referring to FIG. 3A, an isolation layer 105s defining an active region 105a may be formed in a semiconductor substrate 100. The isolation layer 105s may be formed by, e.g., a trench isolation technique. A gate pattern 110 may be formed in the active region 105a. The gate pattern 110 may include a sequentially stacked gate insulating layer and gate electrode on the active region 105a. Further, the gate pattern 110 may include a capping layer formed on the gate electrode.

A gate spacer 113 may be formed on at least one sidewall of the gate pattern 110. Impurity regions 115 may be formed in the active region 105a at both sides of the gate pattern 110. The impurity regions 115 may be defined as source and drain regions.

A lower interlayer insulating layer 120 may be formed on the substrate having the impurity regions 115. A direct contact plug 123 may be formed to penetrate the lower interlayer insulating layer 120, and the direct contact plug 123 may be electrically connected to a selected one region of the impurity regions 115. A conductive line 125 covering the direct contact plug 123 may be formed on the lower interlayer insulating layer 120.

An upper interlayer insulating layer 130 may be formed on the substrate having the conductive line 125. The upper interlayer insulating layer 130 and the lower interlayer insulating layer 120 may constitute an interlayer insulating layer 131. The interlayer insulating layer 131 may be patterned to form a contact hole 131a exposing one region of the impurity regions 115. A region of the impurity regions 115 which is not electrically connected to the direct contact plug 123 may be exposed by the contact hole 131a.

Referring to FIG. 3B, a contact plug 141 filling the contact hole 131a may be formed. The contact plug 141 may be composed of a sequentially stacked metal plug 135 and buffer plug 140. In detail, the metal plug 135 partially filling the contact hole 131a may be formed.

The metal plug 135 may be formed of a metal material which has a good electrical conductivity and a good burial characteristic. The metal plug 135 may be formed of, e.g., tungsten. Forming the metal plug 135 may include forming a metal layer, e.g., a tungsten layer, on the substrate having the contact hole 131a, planarizing the metal layer using a CMP process until the interlayer insulating layer 131 is exposed, and etching-back the planarized metal layer to form a recess region in the contact hole 131a. Subsequently, the buffer plug 140 filling the remaining portion of the contact hole 131a may be formed. The buffer plug 140 may be formed of a conductive material layer having a hardness higher than that of the metal plug 135. The buffer plug 140 may be formed of, e.g., metal nitride, conductive oxide, etc. The metal nitride plug may include, e.g., a titanium nitride layer, a titanium aluminum nitride layer, etc. The conductive oxide plug may include at least one of, e.g., a SrRuO₃ layer, a Y₂(Ba,Cu)O₅ layer, a (La,Sr)CoO₃ layer, a LaNiO₃ layer, a RuO₂ layer, etc.

Referring to FIG. 3C, a conductive protection layer 145, a lower conductive layer 156, a ferroelectric layer 157, and an upper conductive layer 159 may be sequentially stacked on the interlayer insulating layer 131. The conductive protection layer 145 may be formed of a conductive oxide layer which not only prevents hydrogen from diffusing, but also enhances adhesive strength between the upper and lower metals. For example, the conductive protection layer 145 may include at least one of, e.g., a SrRuO₃ layer, a Y₂(Ba,Cu)O₅ layer, a (La,Sr)CoO₃ layer, a LaNiO₃ layer, a RuO₂ layer, etc. The lower conductive layer 156 may be composed of a sequentially stacked first conductive layer 150 and a second conductive layer 155. The first conductive layer 150 may be formed of, e.g., a metal nitride layer. For example, the first conductive layer 150 may include at least one of, e.g., a TiAlN layer, a TiN layer, a TaSiN layer, a TaN layer, a WN layer, etc. The second conductive layer 155 may include a noble metal layer. The second conductive layer 155 may include at least one of, e.g., Pt, Ru, Ir, IrO₂, etc. The ferroelectric layer 157 may include at least one of, e.g., PZT (Pb(Zr,Ti)O₃), SBT (SrBi₂Ta₂O₉), SBTN (SrₓBi_{y}(TaᵢNbⱼ)₂O₉), BLT ((Bi₄₋ₓ,Laₓ)Ti₃O₁₂), etc. The upper conductive layer 159 may include at least one of, e.g., Pt, Ru, Ir, IrO₂, SrRuO₃, etc.

Referring to FIG. 3D, the upper conductive layer 159, the ferroelectric layer 157, the lower conductive layer 156, and the conductive protection layer 145 may be sequentially patterned to form a conductive protection pattern 145a, a lower electrode 156a, a ferroelectric pattern 157a, and an upper electrode 159a, which are sequentially stacked on the contact plug 141. The lower electrode 156a, the ferroelectric pattern 157a, and the upper electrode 159a may constitute a ferroelectric capacitor 160. The lower electrode 156a may be composed of a first conductive pattern 150a and a second conductive pattern 155a. The first conductive pattern 150a may act as a barrier which may prevent the second conductive pattern 155a from being oxidized, may prevent elements constituting the second conductive pattern 155a from diffusing downward, and may prevent elements constituting the layers below the first conductive pattern 150a from diffusing into the second conductive pattern 155a.

The conductive protection pattern 145a may prevent hydrogen atoms from diffusing into the ferroelectric pattern 157a through the bottom of the ferroelectric capacitor 160. That is, the conductive protection pattern 145a may cover the bottom of the ferroelectric capacitor 160, so that external hydrogen atoms may be prevented from diffusing into the ferroelectric pattern 157 through the bottom of the ferroelectric capacitor 160. The conductive protection pattern 145a may also prevent a fine gap between the lower electrode 156a and the contact plug 141 from occurring. That is, there may be no fine gap between the lower electrode 156a and the contact plug 141.

An insulating protection layer 165 may be formed on the substrate having the ferroelectric capacitor 160. The insulating protection layer 165 may be formed of, e.g., an insulating oxide layer. For example, the insulating protection layer 165 may include at least one of, e.g., an Al₂O₃ layer, a SiON layer, a SiN layer, etc. The SiN layer may also be a SiNₓ layer. The insulating protection layer 165 may prevent external hydrogen atoms from diffusing into the ferroelectric capacitor 160, in particular, the ferroelectric pattern 157a.

The insulating protection layer 165 and the conductive protection pattern 145a may entirely cover, i.e., enclose, the ferroelectric capacitor 160, so that they may effectively prevent external hydrogen atoms from diffusing into the ferroelectric capacitor 160. The conductive protection pattern 145a may be formed between the lower electrode 156a and the contact plug 141, so that the conductive protection pattern 145a may prevent a fine gap between the lower electrode 156a and the contact plug 141 from occurring.

A method of fabricating a ferroelectric memory device according to another exemplary embodiment of the present invention will be described with reference to FIGS. 4A to 4C.

Referring to FIG. 4A, a substrate 100 as shown in FIG. 3A may be prepared. The substrate where the contact hole 131a may be formed in the interlayer insulating layer 131, has been described in detail with reference to FIG. 3A in the foregoing exemplary embodiment, and a detailed description thereof will be omitted. A metal plug 235 may partially fill the contact hole 131a. The metal plug 235 may be formed of, e.g., tungsten. Forming the metal plug 235 may include forming a metal layer, e.g., a tungsten layer, on the substrate having the contact hole 131a, planarizing the metal layer using a CMP process until the interlayer insulating layer 131 is exposed, and etching-back the planarized metal layer to form a recess region in the contact hole 131a.

A preliminary conductive protection layer 240 filling the residual portion of the contact hole 131a may be formed on the interlayer insulating layer 131. The preliminary conductive protection layer 240 may be formed of, e.g., a conductive oxide layer. For example, the preliminary conductive protection layer 240 may include at least one of, e.g., a SrRuO₃ layer, a Y₂(Ba,Cu)O₅ layer, a (La,Sr)CoO₃ layer, a LaNiO₃ layer, a RuO₂ layer, etc.

Referring to FIG. 4B, the preliminary conductive protection layer 240 may be partially planarized by a partial CMP process. As a result, a planarized conductive protection layer 240a covering the interlayer insulating layer 131 may be formed. The conductive protection layer 240a may include a lower extension 240b extending downward. The lower extension 240b and the metal plug 235 may fill the contact hole 131a. Accordingly, the metal plug 235 and the lower extension 240b, which sequentially fill the contact hole 131a, may form a contact plug. In this case, the lower extension 240b may be defined as a buffer plug.

Referring to FIG. 4C, a sequentially stacked lower conductive layer, ferroelectric layer, and upper conductive layer may be on the conductive protection layer 240a. Subsequently, the upper conductive layer, the ferroelectric layer, the lower conductive layer, and the conductive protection layer 240a may be sequentially patterned to form a sequentially stacked conductive protection pattern 245a, lower electrode 256a, ferroelectric pattern 257a, and upper electrode 259a. The lower electrode 256a may be composed of a first conductive pattern 250a and a second conductive pattern 255a. The first conductive pattern 250a may act as a barrier which may prevent the second conductive pattern 255a from being oxidized, may prevent elements constituting the second conductive pattern 255a from diffusing downward, and may prevent elements constituting the layers below the first conductive pattern 250a from diffusing into the second conductive pattern 255a. The sequentially stacked lower electrode 256a, ferroelectric pattern 257a, and upper 259a may constitute a ferroelectric capacitor 260.

The conductive protection pattern 245a, and the lower extension extending downward from the conductive protection pattern 245a, i.e., the buffer plug 240b, may prevent hydrogen atoms from penetrating into the ferroelectric pattern 257a through the bottom of the ferroelectric capacitor 260. That is, the conductive protection pattern 245a may cover the bottom of the ferroelectric capacitor 260, so that the conductive protection pattern 245a may prevent external hydrogen atoms from penetrating into the ferroelectric pattern 257a through the bottom of the ferroelectric capacitor 260.

An insulating protection layer 265 may be formed on the substrate having the ferroelectric capacitor 260. The insulating protection layer 265 may be formed of, e.g., an insulating oxide layer. The insulating protection layer 265 may include at least one of, e.g., an Al₂O₃ layer, a SiON layer, a SiN layer, etc. The SiN layer may be a SiNₓ layer. The insulating protection layer 265 may prevent external hydrogen atoms from diffusing into the ferroelectric capacitor 260, in particular, the ferroelectric pattern 257a. That is, the insulating protection layer 265 and the conductive protection pattern 245a may entirely cover, i.e., enclose, the ferroelectric capacitor 260, so that they may effectively prevent external hydrogen atoms from diffusing into the ferroelectric capacitor 260.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A contact structure, comprising:
a semiconductor substrate;
an interlayer insulating layer on the semiconductor substrate;
a contact plug penetrating the interlayer insulating layer, the contact plug being a sequentially stacked metal plug and buffer plug;
a conductive protection pattern covering the contact plug, the conductive protection pattern being a conductive oxide layer; and
a metal pattern on the conductive protection pattern.

2. The contact structure as claimed in claim 1, wherein the metal plug is composed of tungsten.

3. The contact structure as claimed in claim 1, wherein the buffer plug is composed of at least one of metal nitride or conductive oxide.

4. The contact structure as claimed in claim 1, wherein the buffer plug and the conductive protection pattern are formed of a same material during one process.

5. The contact structure as claimed in claim 1, wherein the conductive protection pattern is composed of at least one of a SrRuO₃ layer, a Y₂(Ba,Cu)O₅ layer, a (La,Sr)CoO₃ layer, a LaNiO₃ layer, or a RuO₂ layer.

6. A ferroelectric memory device, comprising:
a semiconductor substrate;
an interlayer insulating layer on the semiconductor substrate;
a contact plug penetrating the interlayer insulating layer, the contact plug being a sequentially stacked metal plug and buffer plug;
a conductive protection pattern covering the contact plug, the conductive protection pattern being a conductive oxide layer;
a lower electrode, a ferroelectric pattern, and an upper electrode sequentially stacked on the conductive protection pattern; and
an insulating protection layer covering the sequentially stacked lower electrode, ferroelectric pattern, and upper electrode.

7. The ferroelectric memory device as claimed in claim 6, wherein the metal plug is composed of tungsten.

8. The ferroelectric memory device as claimed in claim 6, wherein the buffer plug is composed of at least one of metal nitride or conductive oxide.

9. The ferroelectric memory device as claimed in claim 8, wherein the metal nitride plug is composed of at least one of TiN or TiAlN, and the conductive oxide plug is composed of at least one of SrRuO₃, Y₂(Ba,Cu)O₅, (La,Sr)CoO₃, LaNiO₃, or RuO₂.

10. The ferroelectric memory device as claimed in claim 6, wherein the conductive oxide layer is composed of at least one of a SrRuO₃ layer, a Y₂(Ba,Cu)O₅ layer, a (La,Sr)CoO₃ layer, a LaNiO₃ layer, or a RuO₂ layer.

11. The ferroelectric memory device as claimed in claim 6, wherein the lower electrode is formed of a sequentially stacked first conductive pattern and second conductive pattern, the first conductive pattern is composed of at least one of a TiN layer, a TiSiN layer, a TaN layer, a TiAlN layer, or a TaAlN layer, and the second conductive pattern is composed from at least one of a Pt layer, a Ru layer, an Ir layer, or an IrO₂ layer.

12. The ferroelectric memory device as claimed in claim 6, wherein the buffer plug and the conductive protection pattern are formed of a same material during one process.

13. The ferroelectric memory device as claimed in claim 6, wherein the insulating protection layer is composed of at least one of an Al₂O₃ layer, a SiON layer, or a SiN layer.

14. A method of fabricating a ferroelectric memory device, comprising:
forming an interlayer insulating layer having a contact hole on a semiconductor substrate;
forming a contact plug composed of a metal plug and a buffer plug, the metal plug and the buffer plug sequentially filling the contact hole;
forming a conductive protection layer composed of a conductive oxide layer on the substrate having the contact plug;
forming a sequentially stacked lower conductive layer, ferroelectric layer, and upper conductive layer on the conductive protection layer;
sequentially patterning the upper conductive layer, the ferroelectric layer, the lower conductive layer, and the conductive protection layer to form a conductive protection pattern, a lower electrode, a ferroelectric pattern, and an upper electrode, which are sequentially stacked on the contact plug; and
forming an insulating protection layer on the substrate having the conductive protection pattern, the lower electrode, the ferroelectric pattern, and the upper electrode.

15. The method as claimed in claim 14, wherein the buffer plug is composed of at least one of metal nitride or conductive oxide.

16. The method as claimed in claim 14, wherein the conductive oxide layer is composed of at least one of a SrRuO₃ layer, a Y₂(Ba,Cu)O₅ layer, a (La,Sr)CoO₃ layer, a LaNiO₃ layer, or a RuO₂ layer.

17. The method as claimed in claim 14, wherein forming the contact plug comprises:
forming a metal layer on the interlayer insulating layer having the contact hole;
planarizing the metal layer until the interlayer insulating layer is exposed;
etching-back the planarized metal layer to form a metal plug partially filling the contact hole;
forming a buffer conductive layer on the semiconductor substrate having the metal plug; and
planarizing the buffer conductive layer to form a buffer plug filling the remaining portion of the contact hole.

18. The method as claimed in claim 14, wherein the buffer plug is formed while the conductive protection layer is formed.

19. The method as claimed in claim 18, wherein forming the contact plug and the conductive protection layer comprises:
forming a metal plug filling a portion of the contact hole;
forming a conductive oxide layer filling a remainder portion of the contact hole and covering the interlayer insulating layer; and
partially planarizing the conductive oxide layer to make a portion of the conductive oxide layer remain on the interlayer insulating layer by using a partial chemical mechanical polishing (CMP) process.

20. The method as claimed in claim 14, wherein forming the lower conductive layer includes forming a sequentially stacked first conductive layer and second conductive layer, the first conductive layer being formed of at least one of a TiN layer, a TiSiN layer, a TaN layer, a TiAlN layer, or a TaAlN layer, and the second conductive layer being formed of at least one of a Pt layer, a Ru layer, an Ir layer, or an IrO₂ layer.
